(19) United States
(12) Patent Application Publication
(10) Pub. No.: US 2018/0019574 A1
(43) Pub. Date: Jan. 18, 2018

(54) LIGHT EMITTING DEVICE

(71) Applicant: FUJI XEROX CO., LTD., Tokyo (JP)

(72) Inventors: Naoki JOGAN, Kanagawa (JP); Jun SAKURAI, Kanagawa (JP); Akemi MURAKAMI, Kanagawa (JP); Takashi KONDO, Kanagawa (JP); Junichiro HAYAKAWA, Kanagawa (JP)

(73) Assignee: FUJI XEROX CO., LTD., Tokyo (JP)

(21) Appl. No.: 15/496,641

(22) Filed: Apr. 25, 2017

(30) Foreign Application Priority Data
Jul. 12, 2016 (JP) 2016-137341

(51) Int. Cl. H01S 5/22; H01S 5/183

(52) U.S. Cl. CPC H01S 5/2214; H01S 5/183

(57) ABSTRACT

A light emitting device includes:
a first mesa structure including a light emitting part;
a second mesa structure that is connected to the first mesa structure by a common semiconductor layer and that includes a light receiving part that receives light propagating in a lateral direction through the semiconductor layer from the light emitting part;
a detector that detects an amount of the light received by the light receiving part; and
an oxide confinement layer that is formed over the first mesa structure and the second mesa structure and that includes an oxidized region and a non-oxidized region.

### CROSS-REFERENCE TO RELATED APPLICATIONS

This application is based on and claims priority under 35 USC 119 from Japanese Patent Application No. 2016-137341 filed Jul. 12, 2016.

### BACKGROUND

### Technical Field

The present invention relates to a light emitting device.

### SUMMARY

According to an aspect of the invention, alight emitting device includes:

a first mesa structure including a light emitting part;

a second mesa structure that is connected to the first mesa structure by a common semiconductor layer and that includes a light receiving part that receives light propagating in a lateral direction through the semiconductor layer from the light emitting part;

a detector that detects an amount of the light received by the light receiving part; and

an oxide confinement layer that is formed over the first mesa structure and the second mesa structure and that includes an oxidized region and a non-oxidized region.

### BRIEF DESCRIPTION OF THE DRAWINGS

Exemplary embodiments of the present invention will be described in detail based on the following figures, wherein:

FIGS. 1A and 1B are a cross-sectional view and a top plan view illustrating an exemplary configuration of a light emitting device according to a first exemplary embodiment;

FIG. 2 is a view for explaining an operation of the light emitting device according to the exemplary embodiment;

FIGS. 3A and 3B are views for explaining a relationship between an optical output and a monitor current of the light emitting device according to the exemplary embodiment;

FIG. 4 is a view for explaining an APC control of the light emitting device according to the exemplary embodiment;

FIGS. 5A to 5F are a part of cross-sectional views illustrating an exemplary method of manufacturing the light emitting device according to the exemplary embodiment;

FIGS. 6A to 6D are a part of cross-sectional views illustrating an exemplary method of manufacturing the light emitting device according to the exemplary embodiment;

FIGS. 7A and 7B are a cross-sectional view and a top plan view illustrating an exemplary configuration of a light emitting device according to a second exemplary embodiment;

FIGS. 8A and 8B are a part of top plan views illustrating an exemplary configuration of the light emitting device according to a third exemplary embodiment; and

FIGS. 9A and 9B are apart of top plan views illustrating an exemplary configuration of the light emitting device according to the third exemplary embodiment.

### DETAILED DESCRIPTION

Hereinafter, exemplary embodiments of the present invention will be described in detail with reference to the drawings. A light emitting device according to the present exemplary embodiment refers to a monitor PD integrated light emitting device in which a monitor photodiode (hereinafter, referred to as a “monitor PD”) is integrated to receive a part of an optical output from a light emitting part.

### First Exemplary Embodiment

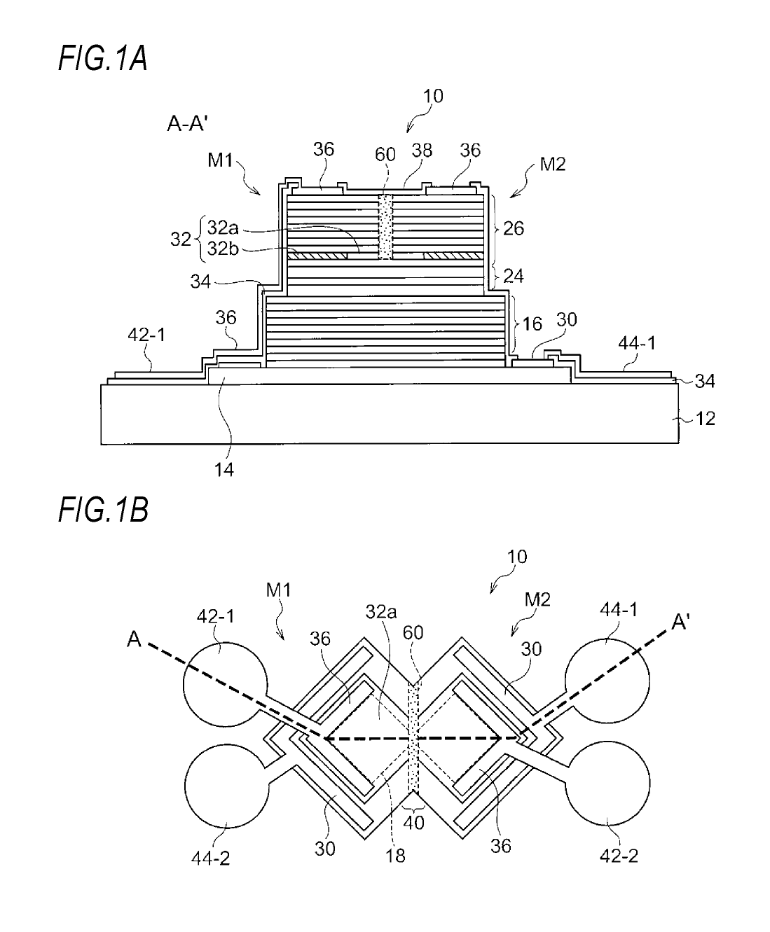

An exemplary configuration of a light emitting device 10 according to the present exemplary embodiment will be described with reference to FIGS. 1A and 1B. In the present exemplary embodiment, descriptions will be made while exemplifying an aspect in which the light emitting device according to the present invention is applied to a vertical cavity surface emitting semiconductor laser (VCSEL: vertical cavity surface emitting laser). FIG. 1A is a cross-sectional view of the light emitting device 10 according to the present exemplary embodiment, and FIG. 1B is a top plan view of the light emitting device 10. The cross-sectional view illustrated in FIG. 1A is a cross-sectional view taken along line A-A′ in the top plan view illustrated in FIG. 1B.

As illustrated in FIG. 1A, the light emitting device 10 includes an n-type GaAs contact layer 14, a lower DBR (distributed Bragg reflector) 16, an active region 24, an oxide confinement layer 32, and an upper DBR 26 which are formed on a semi-insulating GaAs (gallium arsenic) substrate 12.

As illustrated in FIG. 1B, the light emitting device 10 has two mesas (columnar structure), that is, a mesa M1 and a mesa M2 each having a substantially rectangular shape, and has a coupling portion 40 at a portion where the mesa M1 and the mesa M2 are connected to each other. The coupling portion 40 according to the present exemplary embodiment is provided at a narrow portion of a semiconductor layer which is formed as the mesa M1 and the mesa M2 are connected to each other. Each of the mesa M1 and the mesa M2 includes the lower DBR 16, the active region 24, the oxide confinement layer 32, and the upper DBR 26 which are formed in common on the contact layer 14.

In addition, a current blocking region 60, which is formed in the upper DBR 26, is disposed between the mesa M1 and the mesa M2, that is, in the coupling portion 40. The current blocking region 60 according to the present exemplary embodiment is a high resistance region which is formed from upper surfaces of the mesas M1 and M2 over an upper side of the oxide confinement layer 32 (i.e., to a depth that does not reach the active region 24) by, for example, implanting H⁺ (proton) ions, and the current blocking region 60 refers to a region that electrically separates the mesa M1 and the mesa M2 from each other. As described below, in the light emitting device 10 according to the present exemplary embodiment, the mesa M1 constitutes a light emitting part (VCSEL), and the mesa M2 constitutes a light receiving part (monitor photodiode) that receives an optical output from the light emitting part. Hereinafter, the entire structure configured with the mesa M1 and the mesa M2 will be referred to as a mesa M.

Further, the current blocking region 60 serves to improve the detecting precision of the optical output (improve an S/N (signal to noise) ratio) by at least partially and electrically separating the light emitting part and the light receiving part. It should be noted that the current blocking region 60 is not essential. That is, the current blocking region 60 may not to be used depending on an acceptable degree for detecting precision.

As illustrated in FIG. 1A, an interlayer insulating film 34 as an inorganic insulating film is deposited on the circumference of the semiconductor layer including the mesa M. The interlayer insulating film 34 extends from a lateral surface of the mesa M to a surface of the substrate 12, and is disposed under a p-side electrode pad 42-1 and an n-side electrode pad 44-1. The interlayer insulating film 34 according to the present exemplary embodiment is formed of, for example, a silicon nitride film (SiN film). The material of the interlayer insulating film 34 is not limited to the silicon nitride film, but may be, for example, a silicon oxide film (SiO₂ film), a silicon oxynitride film (SiON film), or the like.

As illustrated in FIG. 1A, a p-side electrode wiring 36 is provided through an opening of the interlayer insulating film 34. A contact layer (not illustrated) is provided on the uppermost layer of the upper DBR 26 so as to be connected with the p-side electrode wiring 36, and one end side of the p-side electrode wiring 36 is connected to the upper DBR 26 through the contact layer so that an ohmic contact is formed between the p-side electrode wiring 36 and the upper DBR 26. The other end side of the p-side electrode wiring 36 extends from the lateral surface of the mesa M to the surface of the substrate 12, and constitutes the p-side electrode pad 42-1. The p-side electrode wiring 36 is formed by, for example, depositing a stacked film of Ti (titanium)/Au (gold). Hereinafter, the p-side electrode pad 42-1 and a p-side electrode pad 42-2 (see FIG. 1B) will be collectively referred to as a “p-side electrode pad 42.” In the light emitting device 10, a p-side electrode constitutes an anode electrode.

Similarly, an n-side electrode wiring 30 is provided through an opening of the interlayer insulating film 34. One end side of the n-side electrode wiring 30 is connected to the contact layer 14 so that an ohmic contact is formed between the n-side electrode wiring 30 and the contact layer 14. Meanwhile, the other end side of the n-side electrode wiring 30 extends to the surface of the substrate 12, and forms the n-side electrode pad 44-1 as illustrated in FIG. 1A. The n-side electrode wiring 30 is formed by, for example, depositing a stacked film of AuGe/Ni/Au. Hereinafter, the n-side electrode pad 44-1 and an n-side electrode pad 44-2 (see FIG. 1B) will be collectively referred to as an “n-side electrode pad 44.” In the light emitting device 10, an n-side electrode constitutes a cathode electrode.

As described above, for example, a semi-insulating GaAs substrate is used as the substrate 12 according to the present exemplary embodiment. The semi-insulating GaAs substrate refers to a GaAs substrate which is not doped with impurity. The semi-insulating GaAs substrate has a very high resistivity, and a sheet resistance value thereof is about several megohms (MΩ).

The contact layer 14 formed on the substrate 12 is formed by, for example, a GaAs layer that is doped with Si. One end of the contact layer 14 is connected to the n-type lower DBR 16, and the other end of the contact layer 14 is connected to the n-side electrode wiring 30. That is, the contact layer 14 is interposed between the lower DBR 16 and the n-side electrode wiring 30, and serves to provide a constant electric potential to the semiconductor layer including the mesa M. The contact layer 14 may also serve as a buffer layer provided to improve the crystallinity of the surface of the substrate after thermal cleaning.

Assuming that the oscillation wavelength of the light emitting device 10 is λ and the refractive index of a medium (semiconductor layer) is n, the n-type lower DBR 16 formed on the contact layer 14 is a multilayer reflection mirror configured by repeatedly and alternately stacking two semiconductor layers each of which has a film thickness of 0.25λ/n. The two semiconductor layers have different refractive indexes. Specifically, the lower DBR 16 is configured by repeatedly and alternately stacking an n-type low refractive index layer made of Al_{0.90}Ga_{0.1}As and an n-type high refractive index layer made of Al_{0.15}Ga_{0.85}As. In the light emitting device according to the present exemplary embodiment, the oscillation wavelength λ is 850 nm for example.

The active region 24 according to the present exemplary embodiment may include, for example, a lower spacer layer, a quantum well active layer, and an upper spacer layer (not illustrated). The quantum well active layer according to the present exemplary embodiment may include, for example, four barrier layers made of Al_{0.3}Ga_{0.7}As and three quantum well layers made of GaAs and provided between the barrier layers. In addition, by being disposed between the quantum well active layer and the lower DBR 16 and between the quantum well active layer and the upper DBR 26, respectively, the lower spacer layer and the upper spacer layer also serve to adjust the length of a resonator, and serve as clad layers for confining a carrier. In the light emitting device 10, since the mesa M1 constitutes the VCSEL, the active region 24 in the mesa M1 constitutes a light emitting layer, and since the mesa M2 constitutes the monitor PD, the active region 24 in the mesa M2 substantially serves as a light absorbing layer.

The p-type oxide confinement layer 32 provided on the active region 24 is a current confinement layer, and includes a non-oxidized region 32a and an oxidized region 32b. The current, which flows from the p-side electrode pad 42-1 to the n-side electrode pad 44-2, is throttled by the non-oxidized region 32a. A boundary 18 illustrated in FIG. 1B represents a boundary between the non-oxidized region 32a and the oxidized region 32b. As illustrated in FIG. 1B, the non-oxidized region 32a according to the present exemplary embodiment, which is defined by the boundary 18, has a narrow shape in the coupling portion 40.

The upper DBR 26 formed on the oxide confinement layer 32 is a multilayer reflection mirror configured by repeatedly and alternately stacking two semiconductor layers each of which has a film thickness of 0.25λ/n. The two semiconductor layers have different refractive indexes. Specifically, the upper DBR 26 is configured by repeatedly and alternately stacking a p-type low refractive index layer of Al_{0.90}Ga_{0.1}As and a p-type high refractive index layer of Al_{0.15}Ga_{0.85}As.

An emission surface protective layer 38 is provided on the upper DBR 26 to protect a light emission surface. For example, the emission surface protective layer 38 is formed by depositing a silicon nitride film.

By the way, since the light emitting device (VCSEL) takes out a laser output in a direction perpendicular to the substrate, the light emitting device is easily configured as an array by 2-dimensional integration, and so on, the light emitting device (VCSEL) is used as a writing light source for an electrophotographic system or a light source for optical communication.

The light emitting device includes a pair of distributed Bragg reflectors (the lower DBR 16 and the upper DBR 26) provided on the semiconductor substrate (substrate 12), and an active region (the active region 24 including the active layer, the lower spacer layer, and the upper spacer layer) provided between the pair of distributed Bragg reflectors. The light emitting device is configured such that a current is applied to the active layer by the electrodes (the p-side electrode wiring 36 and the n-side electrode wiring 30) provided at the opposite sides of the distributed Bragg reflector, and laser oscillation occurs in a direction perpendicular to the surface of the substrate such that the oscillated light is emitted from the upper portion of an element (the surface side of the emission surface protective layer 38).

The light emitting device has the oxide confinement layer (oxide confinement layer 32) formed by oxidizing a semiconductor layer including Al in composition thereof from the point of view of the reduction of a threshold current value and the controllability in a transverse mode, and the element is etched in a mesa shape and subjected to an oxidation treatment in order to oxidize the semiconductor layer including Al. Thereafter, a lateral surface having the mesa shape which is exposed by etching processing or the etched surface of the semiconductor is generally covered with an insulating material such as a silicon nitride film or a silicon oxide film.

Meanwhile, the semiconductor laser (not limited to the VCSEL) is required to be stabilized in some cases so that the optical output is not changed in accompany with a change in temperature or a change in power source. As a method for the stabilization, there is an automatic power control (APC) method. The APC method refers to a method of detecting an optical output of the semiconductor laser as a monitor current by using the monitor PD and the like, obtaining a difference value by comparing the detected monitor current with a reference value, and performing a negative feedback control on the optical output of the semiconductor laser by converting a driving current by using the differential value.

Due to the reason that the semiconductor laser and the monitor PD are made of different semiconductor materials, it is difficult to implement a monolithic integration in many cases. In this case, the monitor PD is provided outside the semiconductor laser. Accordingly, if the semiconductor laser and the monitor PD are capable of being integrated with each other in a monolithic manner, the number of components may be reduced. Further, it is also desirable in terms of a stable operation since noise or the like may hardly affect the semiconductor laser and the monitor PD.

Meanwhile, as an exemplary VCSEL obtained by integrating a monitor PD in a monolithic manner, there is known a VCSEL in which a mesa-shaped light emitting part is surrounded by a high resistance region, and a monitor photodiode, which has the same layer structure as the light emitting part, is disposed around the high resistance region such that the lower portion of the light intensity distribution of the light emitting part reaches a light absorbing part of the monitor photodiode. However, in the exemplary VCSEL, since the light emitting part is surrounded by the monitor PD, it is impossible to form the oxide confinement layer in the light emitting part through the oxidation treatment during a manufacturing process. As described above, in the case of a lack of the oxide confinement layer, it is difficult to perform a control such as the reduction of a current threshold value.

Therefore, the light emitting device according to the present exemplary embodiment adopts a structure in which the light emitting part and the monitor PD are formed as an integrated mesa having a common semiconductor layer, a part of the light emitted from the light emitting part is propagated in parallel with the surface of the substrate, and the propagated light is received by the monitor PD. In the light emitting device according to the present exemplary embodiment, since the light emitting part and the monitor PD are formed as the integrated mesa, an oxidation treatment for forming the oxide confinement layer may be performed.

In the light emitting device 10, the non-oxidized region 32a and the oxidized region 32b are formed by the oxidation treatment on the mesa M. The boundary 18 illustrated in FIG. 1B is a boundary between the non-oxidized region 32a and the oxidized region 32b. That is, the non-oxidized region 32a defined by the boundary 18 is formed from the mesa M1 to the mesa M2.

The oxidized region 32b serves as a non-conductive region because the oxidized region 32b is oxidized such that electrical resistance is increased, and the current applied from the p-side electrode pad 42 is confined in the non-oxidized region 32a. In addition, when a semiconductor is oxidized, a refractive index of the semiconductor is generally decreased. Therefore, the refractive index of the non-oxidized region 32a becomes larger than a refractive index of the oxidized region 32b. For this reason, the light emitted from the light emitting part is confined in the non-oxidized region 32a surrounded by the oxidized region 32b having a low refractive index. That is, the light and current are confined in the non-oxidized region 32a by the oxide confinement layer.

In the light emitting device 10, since the non-oxidized region 32a is formed from the light emitting part configured with the mesa M1 to the light receiving part configured with the mesa M2, a part of laser oscillation light generated by the light emitting part is propagated in a direction parallel to the substrate 12 (i.e., a direction intersecting the oscillation direction of the light emitting part (hereinafter, referred to as a “lateral direction” in some cases)), reaches the light receiving part (monitor PD), and then is converted into a current.

As described above, in the light emitting device 10 according to the present exemplary embodiment, a coupling resonator is configured by optically coupling the light emitting part configured with the mesa M1 and the light receiving part configured with the mesa M2, and the light leaking from the light emitting part is propagated to the coupling portion 40, and detected as a monitor current by a detector connected to the light receiving part. That is, according to the light emitting device 10 of the present exemplary embodiment, a high efficient monitor PD integrated light emitting device is implemented in a compact and simple device structure. Since the detector often detects the monitor current by converting the monitor current into a voltage, a current-voltage conversion unit will be described below while exemplifying the current-voltage conversion unit as an exemplary detector.

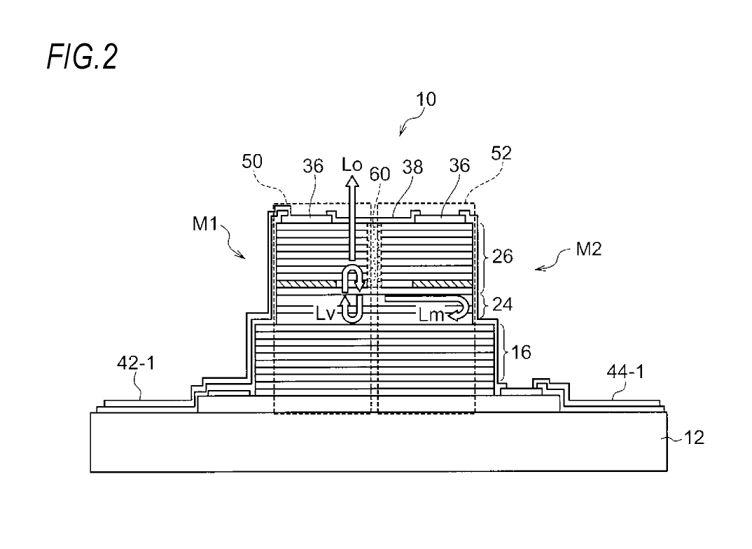

The coupling resonator according to the present exemplary embodiment will be described in more detail with reference to FIG. 2. As described above, in the light emitting device 10, a light emitting part 50 (VCSEL) is formed by the mesa M1, and a light receiving part (monitor PD) 52 is formed by the mesa M2. In the light emitting part 50, a positive pole of a power source (not illustrated) for the VCSEL is connected to the p-side electrode pad 42-1, and a negative pole thereof is connected to the n-side electrode pad 44-2 (forward bias). As the driving current is applied between the p-side electrode pad 42-1 and the n-side electrode pad 44-2, oscillation light Lv is generated by the resonator formed by the lower DBR 16 and the upper DBR 26, as illustrated in FIG. 2. Apart of the oscillation light Lv is emitted, as projection light Lo, from the emission surface protective layer 38.

As illustrated in FIG. 2, a part of the oscillation light Lv is propagated as propagating light Lm (monitor light) in the lateral direction. The propagating light Lm is propagated from the light emitting part 50 to the light receiving part 52 while being totally reflected by the resonator formed by the lower DBR 16 and the upper DBR 26. For this reason, a group velocity of the propagating light Lm is decreased, so that the propagating light Lm becomes so-called slow light. Meanwhile, in the light receiving part 52, a positive pole of a power source (not illustrated) for the monitor PD is connected to the n-side electrode pad 44-1, and a negative pole thereof is connected to the p-side electrode pad 42-2 (reverse bias). As a light receiving current generated by the propagating light Lm is applied between the n-side electrode pad 44-1 and the p-side electrode pad 42-2, the optical output from the light emitting part 50 is monitored. In this case, the light absorbing layer of the light receiving part 52 also serves as the active region 24 that constitutes the light emitting part. For this reason, the light absorbing layer, which constitutes the light receiving part 52, does not necessarily have a sufficient film thickness. However, since the monitor light according to the present exemplary embodiment is the slow light as described above, a carrier is easily generated and a sufficient photocurrent is obtained even in the case where the light absorbing layer is thin.

Next, an operation of the coupling portion 40 according to the present exemplary embodiment will be described. As illustrated in FIG. 1B, the non-oxidized region 32a and the oxidized region 32b are constricted in the coupling portion 40. For this reason, the width of the non-oxidized region 32a is set to be “wide,” “narrow,” and then “wide” from the light emitting part 50 to the light receiving part 52 as illustrated in FIG. 2.

Meanwhile, a ratio of an area of the oxidized region 32b to an area of the non-oxidized region 32a is set to be “small,” “large,” and then “small.” Here, as described above, the refractive index of the non-oxidized region 32a is greater than that of the oxidized region 32b. As known in the related art, as a proportion of materials having a low refractive index is increased around a light waveguide, a refractive index sensed from light propagating through the light waveguide (equivalent refractive index, or effective refractive index) is decreased. For this reason, the equivalent refractive index of the non-oxidized region 32a in the coupling portion 40 is lower than the equivalent refractive index of the non-oxidized region 32a of the light emitting part 50 and the light receiving part 52 at both sides. That is, the equivalent refractive index of the non-oxidized region 32a is set to be “high,” “low,” and then “high” from the light emitting part 50 to the light receiving part 52. The equivalent refractive index used in the present exemplary embodiment refers to an index obtained by an equivalent refractive index method by using an effective refractive index (a refractive index of a multilayered semiconductor layer is considered as a refractive index of a single layer) of semiconductor layers which are stacked in a direction perpendicular to the substrate and have different refractive indexes.

As the light emitting device 10 has an equivalent refractive index distribution of the aforementioned configuration, the light emitted from the light emitting part 50 (VCSEL) is effectively confined in the non-oxidized region 32a, and the light (slow light) leaks from the light emitting part 50 to be received by the light receiving part 52. In a case where the equivalent refractive index of the non-oxidized region 32a is set to be “high,” “high,” and then “high,” from the light emitting part 50 to the light receiving part 52, that is, the equivalent refractive index of the non-oxidized region 32a is set to be substantially constant, it is difficult to confine the light in the light emitting part 50. Meanwhile, in a case where the equivalent refractive index of the non-oxidized region 32a is set to be “high,” “low,” and then “low” from the light emitting part 50 to the light receiving part 52, the light may be confined in the light emitting part 50. However, the amount of leaking light is reduced, and for example, it is difficult to detect the monitor current, and the S/N ratio becomes worse.

In addition, in the present exemplary embodiment, descriptions have been made while exemplifying an aspect in which the equivalent refractive index is set to be “high,” “low,” and then “high” by narrowing the width of the non-oxidized region 32a in the coupling portion 40. It should be noted that the present invention is not limited thereto. For example, the equivalent refractive index may be set to be “high,” “low,” and then “high” by providing a groove at a position of the coupling portion 40 (between the light emitting part 50 and the light receiving part 52). A configuration in which the width is decreased and a configuration in which the groove is provided may be combined. In this case, the groove may be filled with a material (e.g., air) having a refractive index lower than that of the semiconductor layer around the groove.

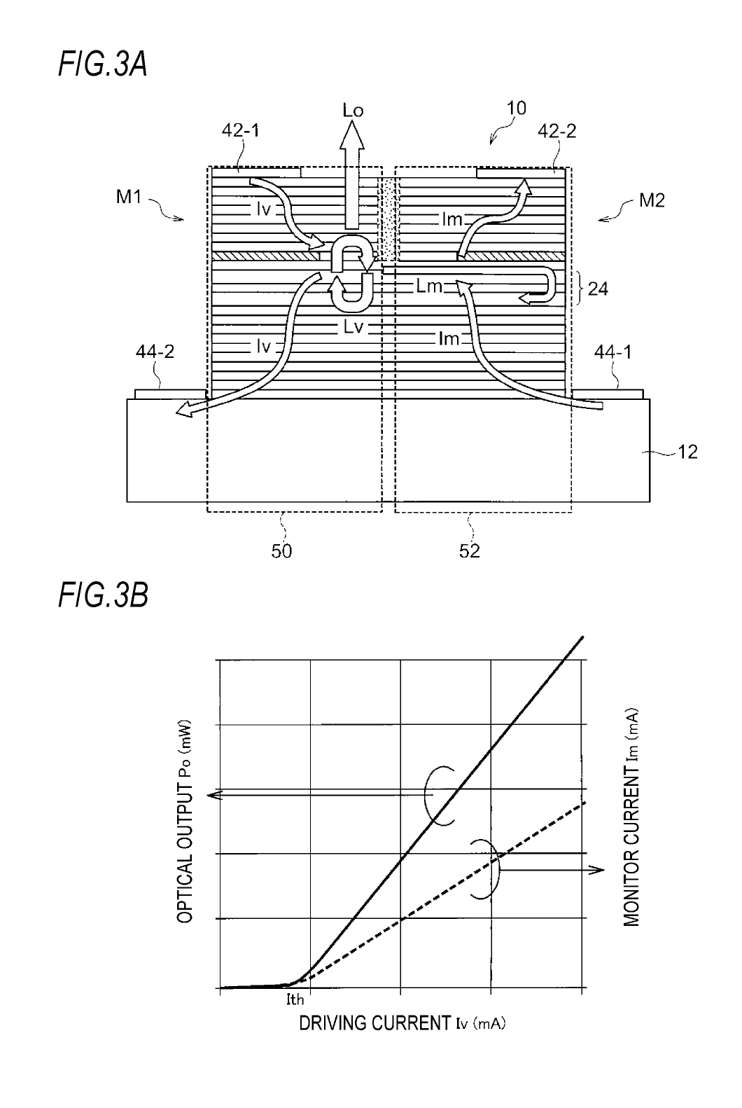

Next, a relationship between the projection light Lo projected from the light emitting part 50 (VCSEL) and a monitor current Im will be described with reference to FIGS. 3A and 3B. In FIG. 3A, the electrode is schematically illustrated for intuitive understanding of a flow of a current. That is, as illustrated in FIG. 3A, the p-side electrode pad 42-1 and the n-side electrode pad 44-2 are connected to the light emitting part 50, and the n-side electrode pad 44-1 and the p-side electrode pad 42-2 are connected to the light receiving part 52.

As illustrated in FIG. 3A, in the light emitting part 50, when the positive pole of the power source (not illustrated) for the VCSEL is connected to the p-side electrode pad 42-1, the negative pole thereof is connected to the n-side electrode pad 44-2, and a driving current Iv is applied between the p-side electrode pad 42-1 and the n-side electrode pad 44-2, the resonator, which is formed by the lower DBR 16 and the upper DBR 26, generates the oscillation light Lv. A part of the oscillation light Lv is projected as the projection light Lo from the light emitting surface (a surface on which the emission surface protective layer 38 is present). Meanwhile, a part of the oscillation light Lv is propagated in the lateral direction as the propagating light Lm, and enters the light receiving part 52. In the light receiving part 52, when the positive pole of the power source (not illustrated) for the monitor PD is connected to the n-side electrode pad 44-1, the negative pole thereof is connected to the p-side electrode pad 42-2, and the monitor current Im (photocurrent) generated by the propagating light Lm is applied between the n-side electrode pad 44-1 and the p-side electrode pad 42-2, an optical output from the light emitting part 50 is monitored. That is, the amount of leaking light of the propagating light Lm in the lateral direction is changed according to the optical output Po of the light emitting part 50 (VCSEL), and the value of the monitor current Im (photocurrent) is changed according to the change amount.

FIG. 3B is a graph illustrating a relationship among the driving current Iv, the optical output Po, which is light power of the outgoing light Lo, and the monitor current Im.

As illustrated in FIG. 3B, the light emitting part 50 (VCSEL) basically generates the optical output Po that is approximately proportional to the driving current Iv, but the light emitting part 50 has an inherent threshold value current (threshold current) Ith, and when the driving current Iv exceeds the threshold value current Ith, the optical output Po is generated. Meanwhile, the monitor current Im is generated approximately in proportion to the optical output Po. Therefore, it is possible to monitor the optical output Po of the light emitting part 50 by using the monitor current Im.

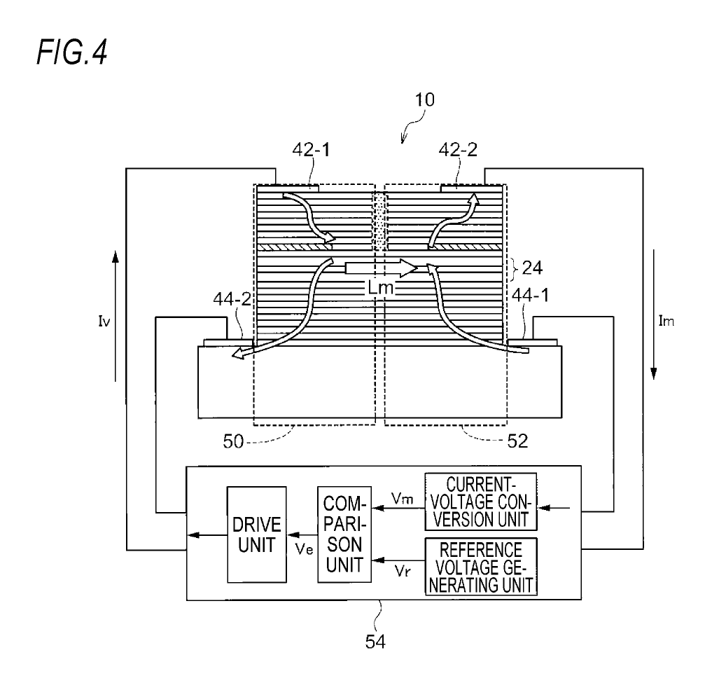

Next, an APC controller 54 will be described with reference to FIG. 4. FIG. 4 illustrates a light emitting device 10 and an APC controller 54 connected to the light emitting device 10.

As illustrated in FIG. 4, the APC controller 54 includes a current-voltage conversion unit, a reference voltage generating unit, a comparison unit, and a drive unit. The current-voltage conversion unit inputs a monitor current Im generated by the light receiving part 52 of the light emitting device 10, and converts the monitor current Im into a monitor voltage Vm. The monitor voltage Vm is also proportional to the optical output Po like the monitor current Im. The reference voltage generating unit is a part that generates a reference voltage Vr with respect to the monitor voltage Vm, and the reference voltage Vr determines a target value of the optical output Po. The current-voltage conversion unit is configured with, for example, a resistance that generates the monitor voltage Vm proportional to the monitor current Im when the monitor current Im is applied thereto. In that event, the monitor current Im may be an input, and the resistance may be a load by using a current mirror circuit that generates current proportional to the monitor current Im. In addition, the current-voltage conversion unit is not limited to these circuits. An amplifier circuit or the like may be provided as necessary.

The comparison unit is apart which compares the monitor voltage Vm and the reference voltage Vr and generates an error voltage Ve, and in an APC control, the error voltage Ve is controlled to be close zero. The drive unit is a part which generates a driving current Iv in accordance with the error voltage Ve, and performs a negative feedback on the light emitting part 50 of the light emitting device 10. The driving current may be driving voltage.

In the light emitting device 10, the optical output Po of the light emitting part 50 is controlled by the APC controller 54 configured as described above, thereby achieving the stabilization of the optical output Po.

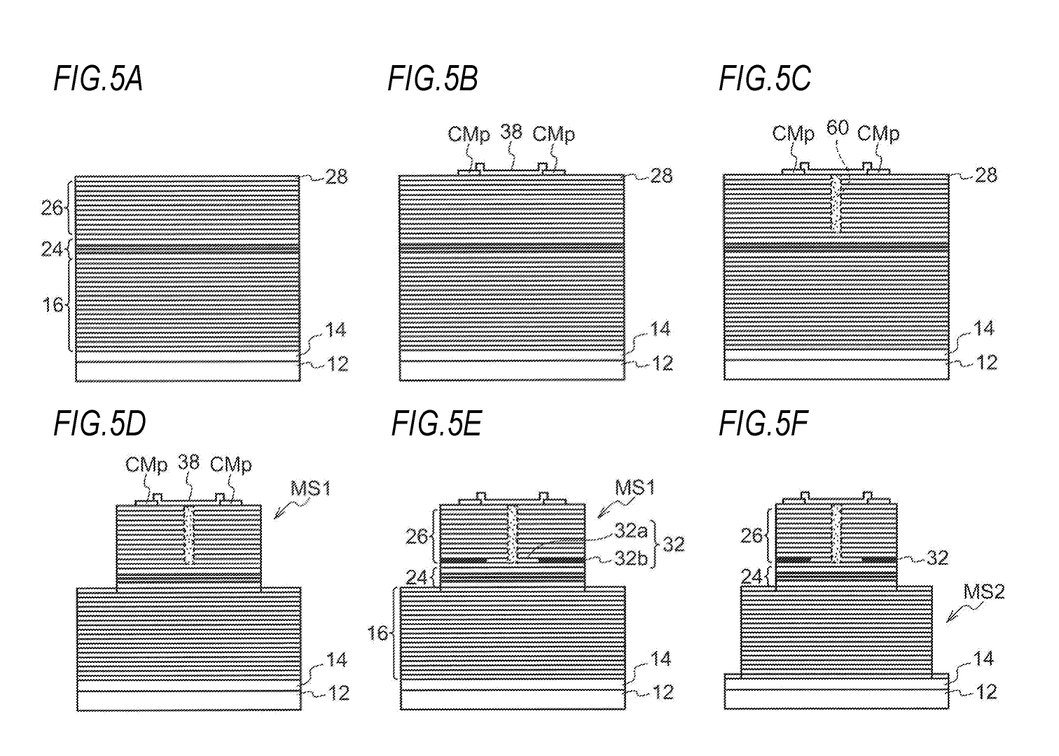

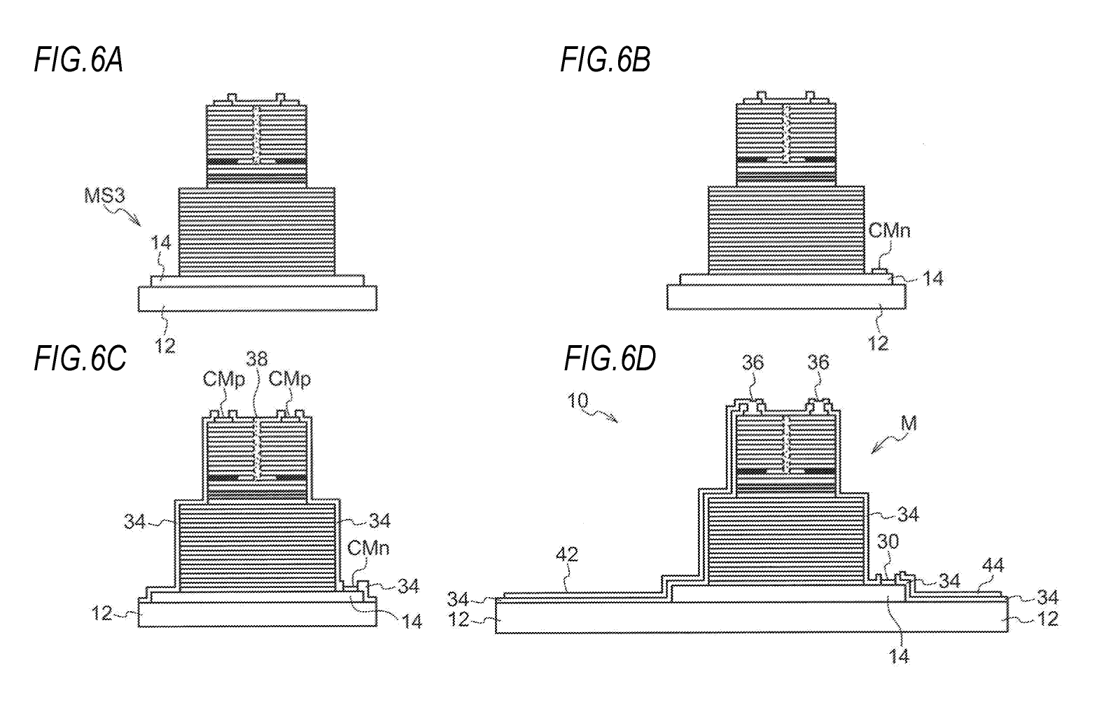

Next, a method of manufacturing the light emitting device 10 according to the exemplary embodiment will be described with reference to FIGS. 5A to 5F and FIGS. 6A to 6D. In the present exemplary embodiment, plural light emitting devices 10 are formed on a single wafer. One of the light emitting devices 10 will be illustrated and described below.

As illustrated in FIG. 5A, first, an n-type contact layer 14, an n-type lower DBR 16, an active region 24, a p-type upper DBR 26, and a p-type contact layer 28 are epitaxially grown in this order on the semi-insulating GaAs substrate 12.

In this regard, for example, the n-type contact layer 14 is formed by setting the carrier concentration to about 2×10¹⁸ cm⁻³ and the film thickness to about 2 μm. For example, the n-type lower DBR 16 is formed by alternately stacking an Al_{0.15}Ga_{0.85}As layer and an Al_{0.9}Ga_{0.1}As layer, each of which has a film thickness of ¼ of an in-medium wavelength λ/n, in 37.5 cycles. Each of the carrier concentration of the Al_{0.3}Ga_{0.7}As layer and the carrier concentration of the Al_{0.9}Ga_{0.1}As layer is about 2×10¹⁸ cm⁻³, and an overall film thickness of the lower DBR 16 is about 4 μm. For example, Si (silicon) is used as the n-type carrier.

The active region 24 includes a lower spacer layer configured as, for example, a non-doped Al_{0.6}Ga_{0.4}As layer, a non-doped quantum well active layer, and an upper spacer layer configured as, for example, a non-doped Al_{0.6}Ga_{0.4}As layer. For example, the quantum well active layer includes four barrier layers made of Al_{0.3}Ga_{0.7}As, and three quantum well layers which are provided among the respective barrier layers and made of GaAs. The film thickness of each of the barrier layers made of Al_{0.3}Ga_{0.7}As is about 8 nm, the film thickness of each of the quantum well layers made of GaAs is about 8 nm, and an overall film thickness of the active region 24 becomes the in-medium wavelength λ/n.

For example, the p-type upper DBR 26 is formed by alternately stacking an Al_{0.15}Ga_{0.85}As layer and an Al_{0.9}Ga_{0.1}As layer, each of which has a film thickness of ¼ of the in-medium wavelength λ/n, in 25 cycles. In this case, each of the carrier concentration of the Al_{0.15}Ga_{0.85}As layer and the carrier concentration of the Al_{0.9}Ga_{0.1}As layer is about 4×10¹⁸ cm⁻³, and an overall film thickness of the upper DBR 26 becomes about 3 μm. For example, C (carbon) is used as the p-type carrier. An AlAs layer, which serves to form the oxide confinement layer 32 during a process to be described below, is included in the upper DBR 26.

The p-type contact layer 28 is formed by setting the carrier concentration to, for example, about 1×10¹⁹ cm⁻³ or more and the film thickness to, for example, about 10 nm.

Next, an electrode material is deposited on the contact layer 28 of the wafer of which the epitaxial growth is completed, and then the material is dry-etched using a mask formed by, for example, photolithography, so that a contact metal CMp for taking out the P-side electrode wiring 36 is formed as illustrated in FIG. 5B. For example, the contact metal CMp is formed by using a stacked film of Ti/Au.

Next, a material, which becomes an emission surface protective layer, is deposited on the surface of the wafer, and then the material is dry-etched using a mask formed by, for example, photolithography, so that the emission surface protective layer 38 is formed as illustrated in FIG. 5B. For example, a silicon nitride film is used as a material of the emission surface protective layer 38.

Next, a mask is formed by photolithography, and then ions such as proton H⁺ are implanted through the emission surface protective layer 38, so that the current blocking region 60 is formed as illustrated in FIG. 5C.

Next, a mask is formed on the surface of the wafer by photolithography and etching, and dry etching is performed using the mask, so that a mesa MS1 is formed as illustrated in FIG. 5D. When forming the mesa MS1, etching is performed so that a mesa M having layers corresponding to the mesas M1 and M2 illustrated in FIG. 1B in a top plan view is formed.

Next, an oxidation treatment is performed on the wafer, and thus the AlAs layer is oxidized from a lateral surface thereof, so that the oxide confinement layer 32 is formed in the mesa MS1 as illustrated in FIG. 5E. The oxide confinement layer 32 includes the non-oxidized region 32a and the oxidized region 32b. The oxidized region 32b is a region which is oxidized by the oxidation treatment, and the non-oxidized region 32a is the remaining region which is not oxidized. As illustrated in FIG. 1B, the non-oxidized region 32a is formed continuously from the mesa M1 to the mesa M2.

Next, a mask is formed on the surface of the wafer by photolithography and etching, and dry etching is performed by using the mask so that a mesa MS2 is formed as illustrated in FIG. 5F.

Next, a mask is formed on the surface of the wafer by photolithography and etching, and dry etching is performed using the mask, so that a mesa MS3 is formed as illustrated in FIG. 6A.

An electrode material is deposited on the contact layer 14, and then the material is dry-etched using a mask formed by, for example, photolithography, so that a contact metal CMn for taking out the n-side electrode wiring 30 is formed as illustrated in FIG. 6D. For example, the contact metal CMn is formed by using a stacked film of AuGe/Ni/Au.

Next, as illustrated in FIG. 6C, the interlayer insulating film 34 configured with a silicon nitride film is deposited in a region except for the emission surface protective layer 38 and the contact metal CMp and CMn of the wafer.

Next, an electrode material is deposited on the surface of the wafer, and then the electrode material is dry-etched using a mask formed by, for example, photolithography, so that the p-side electrode wiring 36, the p-side electrode pad 42, the n-side electrode wiring 30, and the n-side electrode pad 44 are formed as illustrated in FIG. 6D. For example, the p-side electrode wiring 36, the p-side electrode pad 42, the n-side electrode wiring 30, and the n-side electrode pad 44 are formed by using a stacked film of Ti/Au. With the present process, the p-side electrode wiring 36 is connected with the contact metal CMp, and the n-side electrode wiring 30 is connected with the contact metal CMn.

Next, dicing is performed in a dicing region (not illustrated) so that the light emitting device 10 is separated as an individual piece. With the aforementioned processes, a light emitting device 10 including a p-side electrode pad 42 and an n-side electrode pad 44 according to the present exemplary embodiment is manufactured.

### Second Exemplary Embodiment

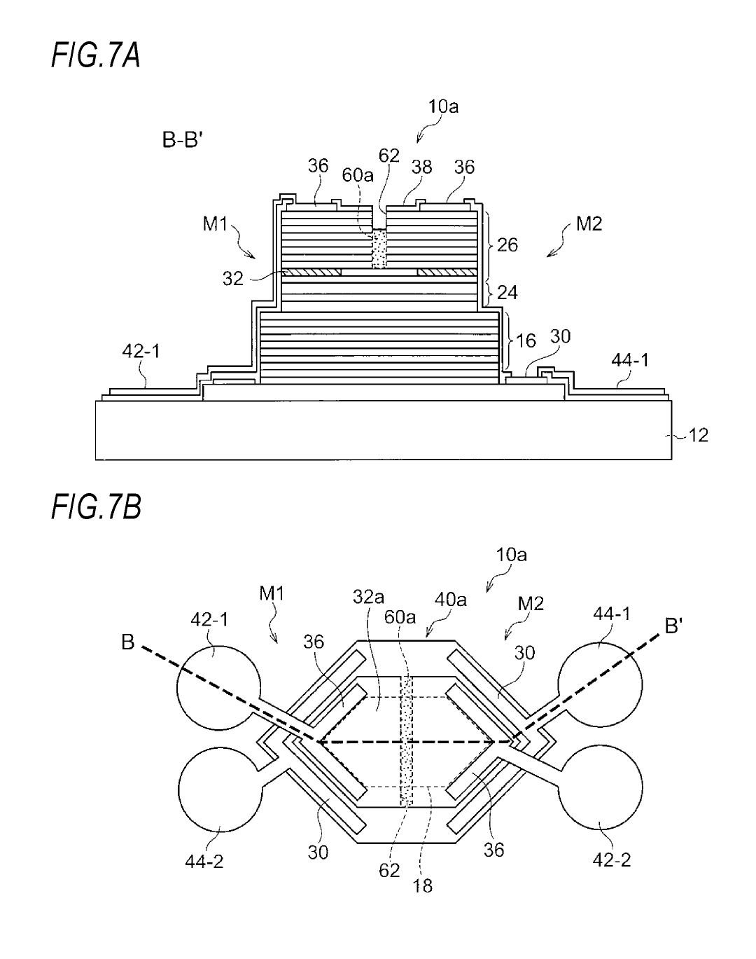

A light emitting device 10a according to the present exemplary embodiment will be described with reference to FIGS. 7A and 7B. The light emitting device 10a has a configuration in which the current blocking region 60 is changed to a current blocking region 60a, the coupling portion 40 is changed to a coupling portion 40a, and a constricted portion of the semiconductor layer is removed. Therefore, the constituent elements except for the current blocking region and the coupling portion are identical to those of the light emitting device 10 of the first exemplary embodiment. The same constituent elements are designated by the same reference numerals, and detailed descriptions thereof will be omitted.

As illustrated in FIGS. 7A and 7B, in the light emitting device 10a, the current blocking region 60a and a recess portion 62 are disposed at a position of the coupling portion 40a disposed between the mesas M1 and M2. The current blocking region 60a differs from the current blocking region 60, and is provided at a part of the upper DBR 26. That is, the current blocking region 60a is formed to a predetermined height of the upper DBR 26 from the top side of the oxide confinement layer 32, and the recess portion 62 is disposed above the current blocking region 60a.

In the light emitting device 10a according to the present exemplary embodiment, the recess portion 62 serves to decrease an equivalent refractive index, and as a result, the equivalent refractive index is set to be “high,” “low,” and then “high” from the mesa M1 to the mesa M2, as illustrated in FIG. 7B, even though a constricted portion is not provided in the semiconductor layer. Therefore, a processed shape of the mesa M is more simplified, the light emitted from the light emitting part is efficiently confined in the non-oxidized region 32a, and the light (slow light) leaks from the light emitting part to be received by the light receiving part 52.

The manufacturing of the light emitting device 10a is performed to be similar to that of the light emitting device 10 according to the first exemplary embodiment. That is, in the case of the light emitting device 10a, the recess portion 62 is formed in advance up to an intermediate portion of the upper DBR 26 in the state illustrated in FIG. 5A, the emission surface protective layer 38 is formed as illustrated in FIG. 5B, and then ions such as proton H⁺ are implanted as illustrated in FIG. 5C, so that the current blocking region 60a may be formed.

In addition, in the aforementioned exemplary embodiment, descriptions have been made while exemplifying an aspect in which both of the recess portion 62 and the current blocking region 60a are employed. It should be noted that the invention is not limited thereto. For example, only the recess portion 62 may be provided. Since the refractive index in the non-oxidized region 32a at the recess portion 62 is decreased as described above, a constricted portion does not always have to be placed at a position of the recess portion 62.

### Third Exemplary Embodiment

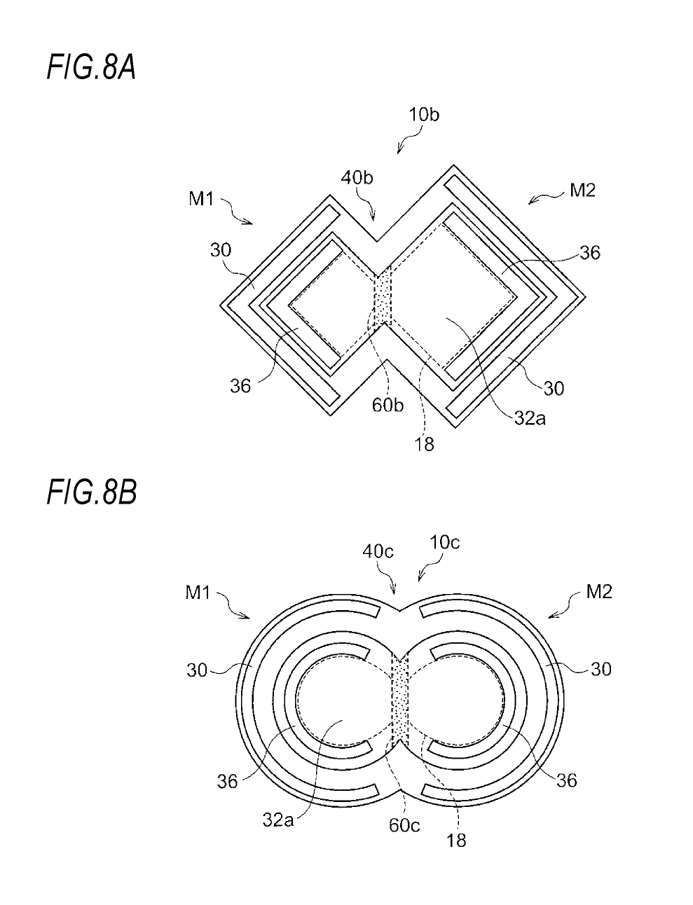

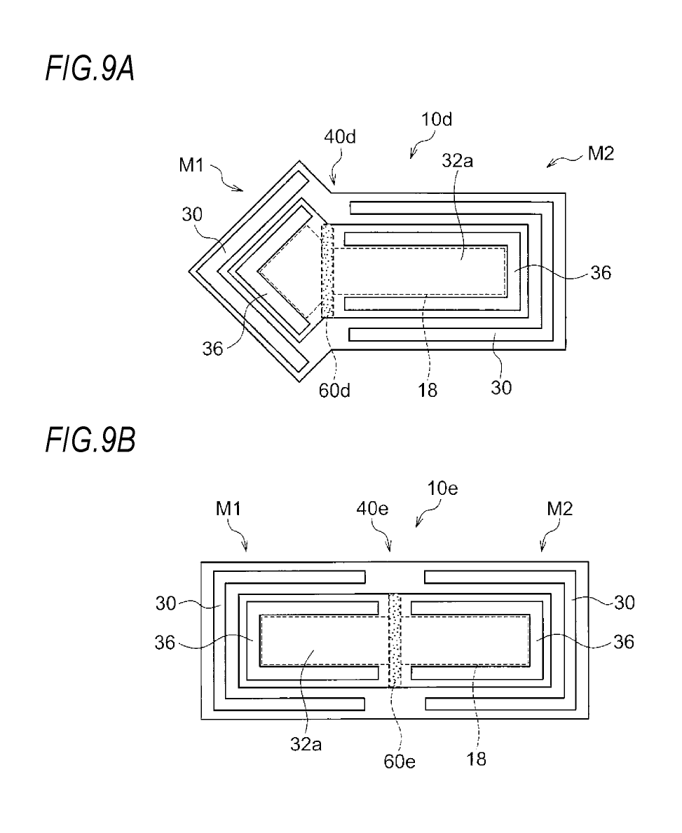

Light emitting devices 10b to 10e according to the present exemplary embodiment will be described with reference to FIGS. 8A and 8B and FIGS. 9A and 9B. In the present exemplary embodiment, shapes of the mesas M and shapes of the coupling portions are changed in the first and second exemplary embodiments.

An example in which the mesas M1 and M2 are symmetrical in a top plan view is described in the first and second exemplary embodiments. It should be noted that the present invention is not limited thereto. For example, the mesas M1 and M2 may be asymmetrical to each other like the light emitting device 10b illustrated in FIG. 8A, and in this case, a shape of a coupling portion 40b is also asymmetrical in a top plan view. In this regard, as illustrated in FIG. 8A, in a case where the mesa M2, which constitutes the light receiving part, is greater than the mesa M1, which constitutes the light emitting part, the detection efficiency of the monitor current Im is improved.

In addition, in each of the aforementioned exemplary embodiment, descriptions have been made while exemplifying an aspect in which the mesa M1 and the mesa M2 have a rectangular shape. It should be noted that the invention is not limited thereto. Alternatively, the mesa M1 and the mesa M2 may have a circular shape like the light emitting device 10c illustrated in FIG. 8B. Since the light emitting devices 10b and 10c have the coupling portions 40b and 40c having constricted portions, respectively, the light emitting devices 10b and 10c may only have current blocking regions 60b and 60c. Of course, the light emitting devices 10b and 10c may further have the current blocking region and the recessed portion.

FIGS. 9A and 9B are a configuration in which a recess portion identical to the recess portion illustrated in FIG. 7A is provided at a position of the coupling portion. As described above, when the recess portion is provided, an equivalent refractive index of the non-oxidized region 32a at a position of the recess portion is decreased. Therefore, a constricted portion does not always have to be provided in the semiconductor layer.

FIG. 9A illustrates a shape of the light emitting device 10d in which the mesa M1 having a substantially square shape and the mesa M2 having a substantially rectangular shape are connected, and no constricted portion is provided in a coupling portion 40d. In the light emitting device 10d, an equivalent refractive index of the mesa M2 is a constant value lower than an equivalent refractive index of the mesa M1. However, with a recess portion (not illustrated) disposed at a position of a current blocking region 60d, an equivalent refractive index at the position of the current blocking region 60d has a value lower than that of an equivalent refractive index of the mesa M2. For this reason, a region, which has an equivalent refractive index lower than that of the mesa M2, is present between the mesa M1 and the mesa M2. Therefore, even in the light emitting device 10d, the light emitted from the light emitting part is efficiently confined in the non-oxidized region 32a, and the light (slow light) leaks from the light emitting part to be received by the light receiving part 52.

FIG. 9B illustrates a shape of a light emitting device 10e in which the mesa M1 and the mesa M2 are formed so that the overall shape of the mesa M is a single rectangular shape, and no constricted portion is provided in a coupling portion 40e. Therefore, an equivalent refractive index of the non-oxidized region 32a is constant from the mesa M1 to the mesa M2. However, with a recess portion disposed at a position of a current blocking region 60e, an equivalent refractive index at the position of the current blocking region 60e becomes a value lower than equivalent refractive indexes of the mesas M1 and M2. For this reason, a region, which has an equivalent refractive index lower than those of the mesas M1 and M2, is present between the mesa M1 and the mesa M2. Therefore, even in the light emitting device 10e, the light emitted from the light emitting part is efficiently confined in the non-oxidized region 32a, and the light (slow light) leaks from the light emitting part to be received by the light receiving part 52.

In addition, in each of the aforementioned exemplary embodiment, descriptions have been made while exemplifying an aspect in which the APC controller 54 and the light emitting device 10 are configured as separate components. It should be noted that the present invention is not limited thereto. For example, the light emitting device 10 and the APC controller 54 may be configured as a single chip by integrating the light emitting device 10 and the APC controller 54 by using the same semiconductor process. In addition, only the current-voltage conversion unit of the APC controller 54 may be integrated with the light emitting device, and in this case, for example, a resistance for detecting a monitor current, or a circuit in which a resistance and a current mirror are combined may be integrated with the light emitting device.

In addition, in the aforementioned exemplary embodiments, descriptions have been made while exemplifying a GaAs-based light emitting device using a semi-insulating GaAs substrate. It should be noted that the invention is not limited thereto. Alternatively, a GaN (gallium nitride) substrate or an InP (indium phosphide) substrate may be used.

Further, in the aforementioned exemplary embodiments, descriptions have been made while exemplifying an aspect in which the n-type contact layer is formed on the substrate. It should be noted that the invention is not limited thereto. Alternatively, a p-type contact layer may be formed on the substrate. In this case, in the aforementioned description, the n-type and the p-type may be reversely read.

The foregoing description of the exemplary embodiments of the present invention has been provided for the purposes of illustration and description. It is not intended to be exhaustive or to limit the invention to the precise forms disclosed. Obviously, many modifications and variations will be apparent to practitioners skilled in the art. The embodiments were chosen and described in order to best explain the principles of the invention and its practical applications, thereby enabling others skilled in the art to understand the invention for various embodiments and with the various modifications as are suited to the particular use contemplated. It is intended that the scope of the invention be defined by the following claims and their equivalents.

What is claimed is:

1. A light emitting device comprising:
a first mesa structure including a light emitting part;
a second mesa structure that is connected to the first mesa structure by a common semiconductor layer and that includes a light receiving part that receives light propagating in a lateral direction through the semiconductor layer from the light emitting part;
a detector that detects an amount of the light received by the light receiving part; and
an oxide confinement layer that is formed over the first mesa structure and the second mesa structure and that includes an oxidized region and a non-oxidized region.

2. The light emitting device according to claim 1, wherein the non-oxidized region has a constricted shape at a connecting portion between the first mesa structure and the second mesa structure when viewed from a light emitting surface side.

3. The light emitting device according to claim 1, wherein a recess portion is formed between the first mesa structure and the second mesa structure from an upper surface of the light emitting part to a depth that does not reach an active layer of the light emitting part.

4. The light emitting device according to claim 2, wherein a recess portion is formed between the first mesa structure and the second mesa structure from an upper surface of the light emitting part to a depth that does not reach an active layer of the light emitting part.

5. The light emitting device according to claim 1, wherein a current blocking region that blocks a flow of a current is formed between the first mesa structure and the second mesa structure.

6. The light emitting device according to claim 2, wherein a current blocking region that blocks a flow of a current is formed between the first mesa structure and the second mesa structure.

7. The light emitting device according to claim 3, wherein a current blocking region that blocks a flow of a current is formed between the first mesa structure and the second mesa structure.

8. The light emitting device according to claim 4, wherein a current blocking region that blocks a flow of a current is formed between the first mesa structure and the second mesa structure.

9. The light emitting device according to claim 1, wherein an area of the second mesa structure is greater than that of the first mesa structure when viewed from the light emitting surface side.

10. The light emitting device according to claim 2, wherein an area of the second mesa structure is greater than that of the first mesa structure when viewed from the light emitting surface side.

11. The light emitting device according to claim 3, wherein an area of the second mesa structure is greater than that of the first mesa structure when viewed from the light emitting surface side.

12. The light emitting device according to claim 4, wherein an area of the second mesa structure is greater than that of the first mesa structure when viewed from the light emitting surface side.

13. The light emitting device according to claim 5, wherein an area of the second mesa structure is greater than that of the first mesa structure when viewed from the light emitting surface side.

14. The light emitting device according to claim 6, wherein an area of the second mesa structure is greater than that of the first mesa structure when viewed from the light emitting surface side.

15. The light emitting device according to claim 7, wherein an area of the second mesa structure is greater than that of the first mesa structure when viewed from the light emitting surface side.

16. The light emitting device according to claim 8, wherein an area of the second mesa structure is greater than that of the first mesa structure when viewed from the light emitting surface side.
